(19) United States
(12) Patent Application Publication
(10) Pub. No.: US 2026/0136725 A1
(43) Pub. Date: May 14, 2026

(54) OPTICAL SUBSTRATE AND MANUFACTURING METHOD THEREOF

(71) Applicant: Innolux Corporation, Miaoli County (TW)

(72) Inventors: Yi-An Chen, Miaoli County (TW); Wan-Ling Huang, Miaoli County (TW); Tsau-Hua Hsieh, Miaoli County (TW)

(73) Assignee: Innolux Corporation, Miaoli County (TW)

(21) Appl. No.: 19/443,042

(22) Filed: Jan. 8, 2026

Related U.S. Application Data
(63) Continuation of application No. 17/731,255, filed on Apr. 27, 2022.

(30) Foreign Application Priority Data
May 11, 2021 (CN) 202110512884.9

(51) Int. Cl. H10H 20/851; H10H 20/01; H10H 20/84; H10H 20/853; H10W 90/00

(52) U.S. Cl. CPC H10H 20/8514; H10H 20/01; H10H 20/84; H10H 20/853; H10W 90/00; H10H 20/034; H10H 20/0361; H10H 20/0362

(57) ABSTRACT

An optical substrate and a manufacturing method thereof are provided. The optical substrate includes a base layer, a bank layer, a wavelength conversion unit, and a first encapsulating layer. The bank layer is disposed on the base layer and includes a first bank portion separated from an edge of the base layer. The wavelength conversion unit is disposed on the base layer and is adjacent to a side of the first bank portion away from the edge. The first encapsulating layer is disposed on the bank layer, the wavelength conversion unit, and a portion of the base layer not covered by the bank layer and the wavelength conversion unit. In the optical substrate and the manufacturing method thereof provided by the embodiments of the disclosure, infiltration of water vapor may be reduced or reliability may be improved.

### CROSS-REFERENCE TO RELATED APPLICATION

This is a continuation application of and claims the priority benefit of U.S. application Ser. No. 17/731,255, filed on Apr. 27, 2022, which claims the priority benefit of China application serial no. 202110512884.9, filed on May 11, 2021. The entirety of each of the above-mentioned patent applications is hereby incorporated by reference herein and made a part of this specification.

### BACKGROUND

### Technical Field

The disclosure relates to an optical substrate and a manufacturing method thereof, and in particular, relates to an optical substrate and a manufacturing method thereof through which infiltration of water vapor may be reduced or reliability may be improved.

### Description of Related Art

Display panels have been widely applied in electronic devices such as mobile phones, televisions, monitors, tablet computers, car displays, wearable devices, and desktop computers. With the vigorous development of electronic products, the demand for improved display quality of the electronic products continues to grow, and as such, the electronic devices used for display aim to provide more reliable display effects.

### SUMMARY

The disclosure provides an optical substrate and a manufacturing method thereof through which infiltration of water vapor may be reduced or reliability may be improved.

According to an embodiment of the disclosure, an optical substrate includes a base layer, a bank layer, a wavelength conversion unit, and a first encapsulating layer. The bank layer is disposed on the base layer and includes a first bank portion separated from an edge of the base layer. The wavelength conversion unit is disposed on the base layer and is adjacent to a side of the first bank portion away from the edge. The first encapsulating layer is disposed on the bank layer, the wavelength conversion unit, and a portion of the base layer not covered by the bank layer and the wavelength conversion unit.

According to an embodiment of the disclosure, a manufacturing method of an optical substrate includes the following steps. A base layer is provided. A bank layer is formed on the base layer. Herein, the bank layer has a first opening and a second opening. A wavelength conversion unit is formed in the first opening. A first encapsulating layer is formed on the bank layer, the wavelength conversion unit, and a portion of the base layer corresponding to the second opening.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 1E are local cross-sectional schematic views of a manufacturing method of an optical substrate according to a first embodiment of the disclosure.

FIG. 2A to FIG. 2C are local cross-sectional schematic views of a manufacturing method of an optical substrate according to a second embodiment of the disclosure.

FIG. 3A to FIG. 3C are local cross-sectional schematic views of a manufacturing method of an optical substrate according to a third embodiment of the disclosure.

FIG. 4A to FIG. 4C are local cross-sectional schematic views of a manufacturing method of an optical substrate according to a fourth embodiment of the disclosure.

### DESCRIPTION OF THE EMBODIMENTS

The accompanying drawings are included together with the detailed description provided below to provide a further understanding of the disclosure. Note that in order to make the accompanying drawings to be more comprehensible to readers and for the sake of clarity of the accompanying drawings, only part of the electronic device is depicted in the accompanying drawings of the disclosure, and specific components in the drawings are not depicted according to actual scales. In addition, the numbers and sizes of the components in each drawing are provided for illustration only and are not used to limit the scope of the disclosure.

In the following specification and claims, the words “containing” and “including” are open-ended words and therefore should be interpreted as “containing but not limited to . . . ”.

It should be understood that when a component or a film layer is referred to as being “on” or “connected to” another component or film layer, it can be directly on the another component or film layer or be directly connected to the another component or film layer, or an inserted component or film layer may be provided therebetween (not a direct connection). In contrast, when the component is referred to as being “directly on” another component or film layer or “directly connected to” another component or film layer, an inserted component or film layer is not provided therebetween.

Although the terms “first”, “second”, “third” . . . may be used to describe various components, the components are not limited to these terms. These terms are only used to distinguish a single component from other components in the specification. The same terms may not be used in the claims, and the components in the claims may be replaced with first, second, third . . . according to the order declared by the components in the claims. Therefore, in the following description, the first component may be the second component in the claims.

In the text, the terms “about”, “approximately”, “substantially”, and “roughly” usually mean within 10%, 5%, 3%, 2%, 1%, or 0.5% of a given value or range. The number given here is an approximate number, that is, the meanings of “about”, “approximately”, “substantially”, and “roughly” may still be implied without specifying “about”, “approximately”, “substantially”, and “roughly”. In addition, the wordings “the range is from the first numerical value to the second numerical value” and “the range falls between the first numerical value and the second numerical value” mean that the range includes the first numerical value, the second numerical value, and other numerical values therebetween.

In some embodiments of the disclosure, regarding the words such as “connected”, “interconnected”, etc. referring to bonding and connection, unless specifically defined, these words mean that two structures are in direct contact or two structures are not in direct contact, and other structures are provided to be disposed between the two structures. The word for joining and connecting may also include the case where both structures are movable or both structures are fixed. In addition, the word “coupled” may include any direct or indirect electrical connection means.

In the disclosure, the length, width, thickness, height, area, or the distance or spacing between components may be measured by an optical microscope (OM), a scanning electron microscope (SEM), a film thickness profile measuring instrument (α-step), an elliptical thickness measuring instrument, or other suitable methods. To be specific, according to some embodiments, a scanning electron microscope may be used to obtain an image of the cross-sectional structure of the component to be measured, and to measure the width, thickness, height, or area of each component, or the distance or spacing between the components, but it is not limited thereto. In addition, a certain error may be provided between any two values or directions used for comparison.

The optical substrate provided by the disclosure may be applied to an electronic device such as a display device, an antenna device (e.g., a liquid crystal antenna), a sensing device, a light emitting device, a touch device, or a spliced device, but it is not limited thereto. The electronic device may include a bendable and flexible electronic device. The appearance of the electronic device may be rectangular, circular, polygonal, or a shape with curved edges, or other suitable shapes. The display device may include but not limited to a light emitting diode (LED), liquid crystal, fluorescence, phosphor, or quantum dot (QD) material, other suitable materials, or a combination of the foregoing, for example. The light emitting diode may include but not limited to an organic LED (OLED), an inorganic LED, a mini LED, a micro LED, or a QD LED (QDLED), other suitable materials, or a combination of the foregoing, for example. The display device may also include but not limited to a spliced display device, for example. The antenna device may be but not limited to a liquid crystal antenna, for example. The antenna device may include but not limited to an antenna spliced device, for example. Note that the electronic device may be any combination of the foregoing, but is not limited thereto. Besides, the appearance of the electronic device may be rectangular, circular, polygonal, or a shape with curved edges, or other suitable shapes. The electronic device may have a peripheral system such as a driving system, a control system, a light source system, a shelf system, etc., to support the display device, the antenna device, or the spliced device. Hereinafter, an optical substrate is provided herein to describe the content of the disclosure, but the disclosure is not limited thereto.

It should be understood that in the following embodiments, the features of several different embodiments may be replaced, recombined, and mixed to complete other embodiments without departing from the spirit of the disclosure. As long as the features of the embodiments do not violate or do not conflict with the spirit of the disclosure, they may be mixed and matched arbitrarily.

Descriptions of the disclosure are given with reference to the exemplary embodiments illustrated by the accompanying drawings. Wherever possible, the same reference numbers are used in the drawings and the description to refer to the same or like parts.

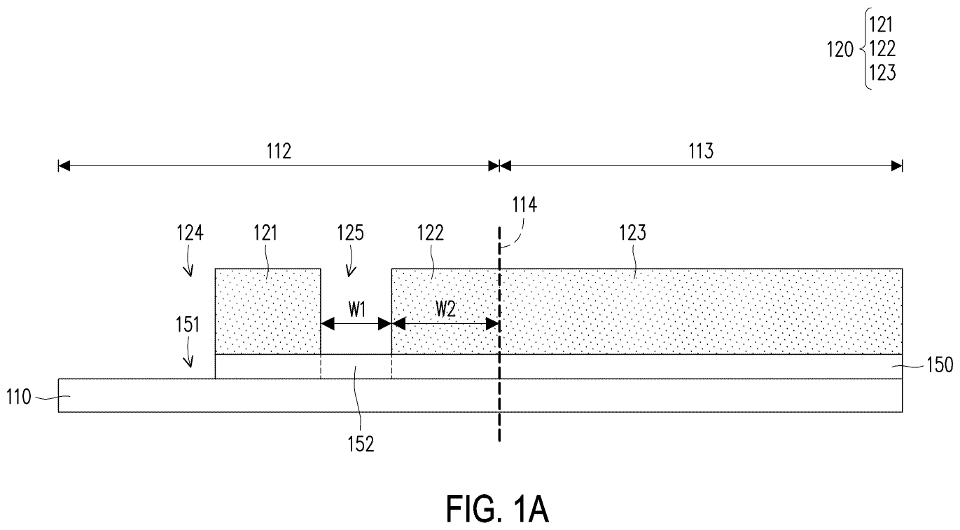

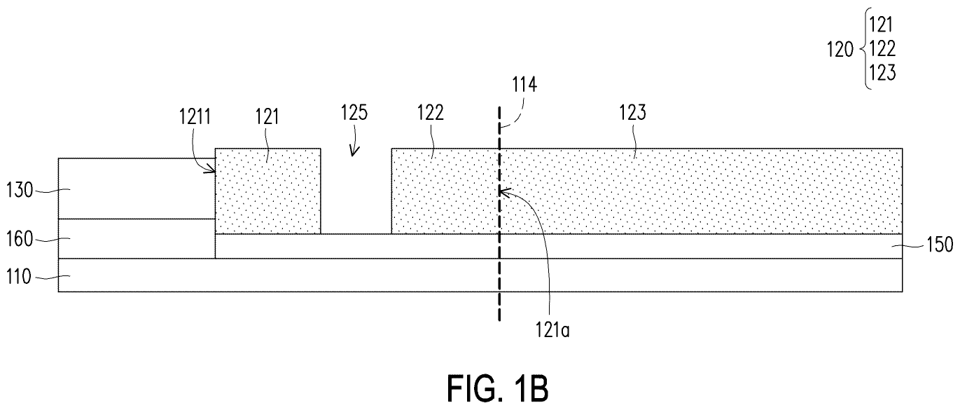

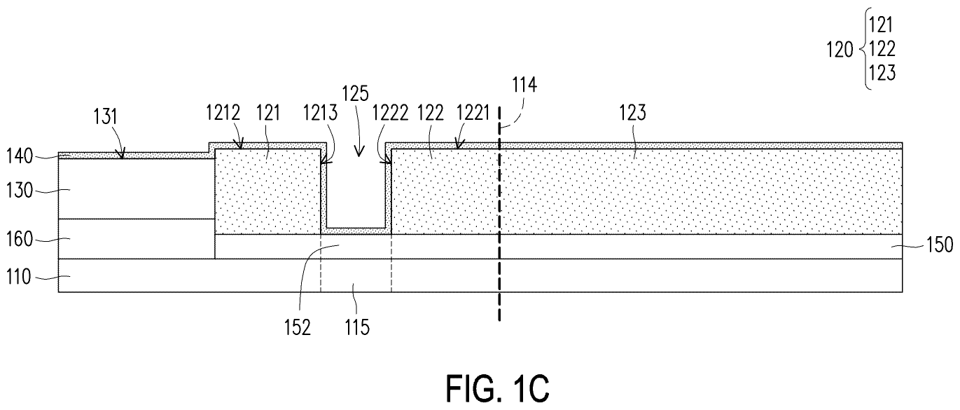

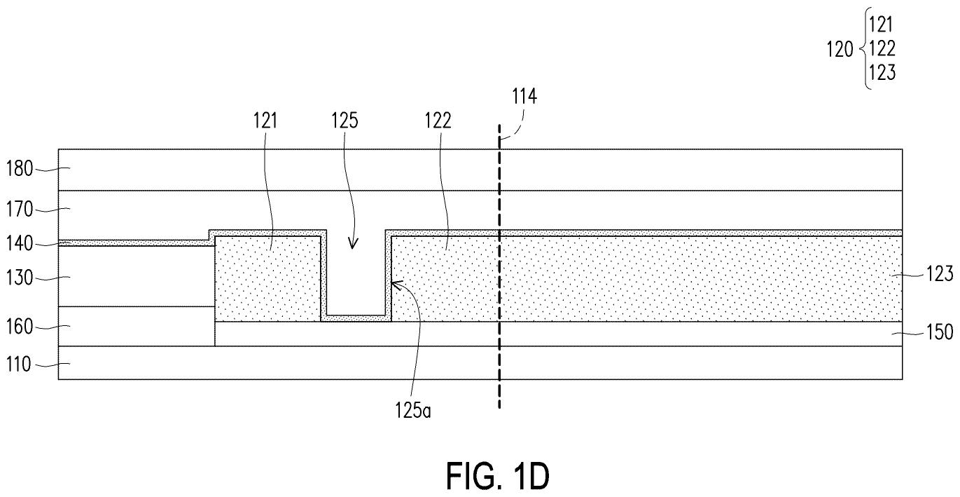

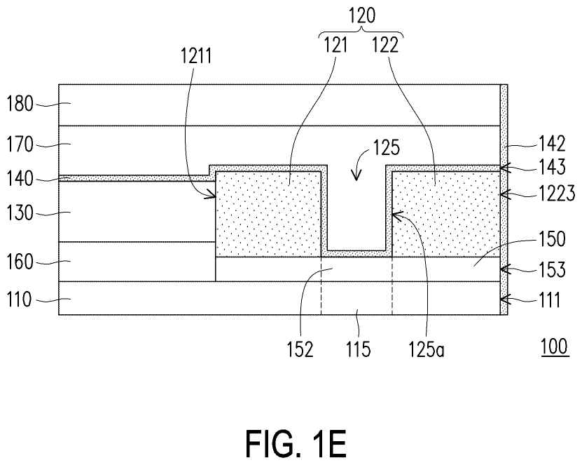

FIG. 1A to FIG. 1E are local cross-sectional schematic views of a manufacturing method of an optical substrate according to a first embodiment of the disclosure. With reference to FIG. 1E first, an optical substrate 100 provided by this claim may include a base layer 110, a bank layer 120, a wavelength conversion unit 130, and a first encapsulating layer 140. Herein, the bank layer 120 is disposed on the base layer 110, and the bank layer 120 includes a first bank portion 121 separated from an edge 111 of the base layer 110. The wavelength conversion unit 130 is disposed on the base layer 110, and the wavelength conversion unit 130 is adjacent to a side 1211 of the first bank portion 121 away from the edge 111. The first encapsulating layer 140 is disposed on the bank layer 120, the wavelength conversion unit 130, and a portion 115 of the base layer 110 not covered by the bank layer 120 and the wavelength conversion unit 130. In the disclosure, one component covering another component means that the two components overlap each other in a normal direction of the base layer 110.

A manufacturing method of the optical substrate 100 provided by this embodiment is described as follows.

With reference to FIG. 1A first, the base layer 110 is provided first. The base layer 110 may include an active region 112, a frame region 113, and a cutting line 114. The cutting line 114 is disposed at a junction between the active region 112 and the frame region 113. In this embodiment, the frame region 113 may be cut off in a subsequent cutting step, and the active region 112 is reserved as a part of the electronic device. In this embodiment, the base layer 110 may be, for example, a rigid substrate, a flexible substrate, or a combination of the foregoing. For instance, a material of the base layer 110 may include but not limited to glass, quartz, sapphire, ceramics, polycarbonate (PC), polyimide (PI), polyethylene terephthalate (PET), other suitable substrate materials, or a combination of the foregoing materials.

Next, before the bank layer 120 is formed on the base layer 110, a black matrix layer 150 may be formed on the base layer 110 first. The black matrix layer 150 may include an opening 151 disposed in the active region 112. Herein, the opening 151 may expose a portion of the base layer 110. In some embodiments, a material of the black matrix layer 150 may include but not limited to a light-absorbing material such as black matrix (BM) resin or other suitable light-absorbing materials.

Next, the bank layer 120 is formed on the base layer 110. In this embodiment, the bank layer 120 is disposed on the black matrix layer 150, so that the black matrix layer 150 may be disposed between the base layer 110 and the bank layer 120, and the bank layer 120 may be substantially overlap with the black matrix layer 150 in the normal direction of the base layer 110. The bank layer 120 may include the first bank portion 121, a second bank portion 122, a third bank portion 123, a first opening 124, and a second opening 125. The first bank portion 121, the second bank portion 122, the first opening 124, and the second opening 125 are disposed in the active region 112, and the third bank portion 123 is disposed in the frame region 113. Herein, the cutting line 114 may also be disposed at a junction between the second bank portion 122 and the third bank portion 123.

To be specific, the first opening 124 may be connected to and overlap with the opening 151 of the black matrix layer 150, so that the first opening 124 and the opening 151 may expose a portion of the base layer 110. The second opening 125 is disposed between the first bank portion 121 and the second bank portion 122. The second opening 125 may expose a portion 152 of the black matrix layer 150, so that the portion 152 of the black matrix layer 150 is not covered by the bank layer 120. The second opening 125 may be closer to the cutting line 114 of the base layer 110 than the first opening 124. Besides, a width W1 of the second opening 125 may be greater than or equal to 3 nm (i.e., W1≥3 nm), for example, but it is not limited thereto. Herein, the width W1 is, for example, a maximum width of the second opening 125 measured in an extending direction of the local cross-sectional view, and the extending direction of the local cross-sectional view is perpendicular to the normal direction of the base layer 110.

The second bank portion 122 may be separated from the first bank portion 121 through the second opening 125. The second bank portion 122 may be closer to the cutting line 114 of the base layer 110 than the first bank portion 121. A width W2 of the second bank portion 122 may be greater than 0 nm (i.e., W2>0 nm), for example, but it is not limited thereto. Herein, the width W2 is, for example, a maximum width of the second bank portion 122 measured in the extending direction of the local cross-sectional view. Besides, in this embodiment, a material of the bank layer 120 may include but not limited to a light-absorbing material and/or a reflective material, such as a photoresist material (e.g., acrylic resin or siloxane), black resin, a metal material, other suitable materials, or a combination of the foregoing materials.

Next, with reference to FIG. 1B, a color filtering layer 160 is formed in the opening 151, and the wavelength conversion unit 130 is formed in the first opening 124. In this embodiment, the color filtering layer 160 may cover the portion of the base layer 110 exposed by the opening 151. The color filtering layer 160 may be disposed between wavelength conversion unit 130 and the base layer 110. The color filtering layer 160 may include a red filtering layer, a green filter layer, a blue filtering layer, or other suitable color filtering layers, but it is not limited thereto. The color filtering layer 160 may be formed in the opening 151 through, for example, a yellow photolithography process or an ink-jet printing (IJP) process, but it is not limited thereto.

Besides, in this embodiment, the wavelength conversion unit 130 may cover the color filtering layer 160. The wavelength conversion unit 130 may be adjacent to the side 1211 of the first bank portion 121 away from the edge 111. The wavelength conversion unit 130 may include quantum dots, fluorescence, phosphorescence, other suitable materials, or a combination of the foregoing materials, but it is not limited thereto. The wavelength conversion unit 130 may be configured to cover a first light ray provided by a light-emitting unit (not shown) into a second light ray. The first light ray has a first peak wavelength, the second light ray has a second peak wavelength, and the first peak wavelength is less than the second peak wavelength. The wavelength conversion unit 130 may be formed in the first opening 124 through, for example, a yellow photolithography process or an ink-jet printing process, but it is not limited thereto.

Next, with reference to FIG. 1C, the first encapsulating layer 140 is formed on the bank layer 120, the wavelength conversion unit 130, and the portion 115 of the base layer 110 corresponding to the second opening 125 together through an once processing method. To be specific, in this embodiment, the first encapsulating layer 140 may contact and cover a top surface 131 of the wavelength conversion unit 130, the first encapsulating layer 140 may contact and cover a top surface 1212 and a side surface 1213 of the first bank portion 121, and the first encapsulating layer 140 may contact and cover a top surface 1221 and a side surface 1222 of the second bank portion 122. Herein, the top surface 131 of the wavelength conversion unit 130 is the surface of the wavelength conversion unit 130 away from the base layer 110, the top surface 1212 of the first bank portion 121 is the surface of the first bank portion 121 away from the base layer 110, and the top surface 1221 of the second bank portion 122 is the surface of the second bank portion 122 away from the base layer 110. The side surface 1213 of the first bank portion 121 is the surface of the first bank portion 121 adjacent to the second opening 125, and the side surface 1222 of the second bank portion 122 is the surface of the second bank portion 122 adjacent to the second opening 125.

In this embodiment, through once processing, the first encapsulating layer 140 featuring a water-resist effect may contact and cover the top surface 1212 and the side surface 1213 of the first bank portion 121 of the bank layer 120 together, and in this way, infiltration caused water vapor passing through the first bank portion 121 may be accordingly reduced. In turn, reliability of the optical substrate 100 provided by this embodiment may be improved, especially for the optical substrate 100 including the wavelength conversion unit 130 that is susceptible to failure as affected by external water vapor or for a spliced display (zero border tiling display) including the optical substrate 100, but it is not limited thereto.

In this embodiment, since the second opening 125 of the bank layer 120, the portion 152 of the black matrix layer 150, and the portion 115 of the base layer 110 may overlap with one another in the normal direction of the base layer 110, the first encapsulating layer 140 may contact and cover the portion 152 of the black matrix layer 150 through the second opening 125. In this embodiment, a material of the first encapsulating layer 140 may include but not limited to silicon nitride (SiNₓ), silicon oxide (SiOₓ), silicon oxynitride (SiOₓN_{y}), and aluminum oxide (Al₂O₃), other transparent inorganic compounds having a water-resist effect, or a combination of the foregoing. A manufacturing method of the first encapsulating layer 140 may include but not limited to chemical vapor deposition (CVD), atomic layer deposition (ALD), spin coating, spray coating, physical vapor deposition (PVD), ink-jet printing, or other suitable coating processes.

Next, with reference to FIG. 1D and FIG. 1E together, after an adhesive layer 170 is formed on the first encapsulating layer 140 and a driver substrate 180 is disposed on the adhesive layer 170, the base layer 110, the black matrix layer 150, the bank layer 120, the first encapsulating layer 140, the adhesive layer 170, and the driver substrate 180 are cut along the cutting line 114. Herein, the cutting line 114 is adjacent to a side 125a of the second opening 125 away from the first opening 124, and the cutting line 114 does not overlap with the second opening 125. In this embodiment, a material of the adhesive layer 170 may include but not limited to an optically clear adhesive (OCA), optical clear resin (OCR), other suitable transparent materials, or a combination of the foregoing materials. In this embodiment, the driver substrate 180 may include but not limited to a driver circuit (not shown) such as a transistor (TFT), a scan line, and a data line and a light emitting unit (not shown). Besides, in other embodiments, before the adhesive layer 170 is formed on the first encapsulating layer 140 and the driver substrate 180 is disposed on the adhesive layer 170, the base layer 110, the black matrix layer 150, the bank layer 120, and the first encapsulating layer 140 may be cut along the cutting line 114. In the disclosure, the cutting may be performed by a laser, a wheel cutter, or an etching process, but it is not limited thereto.

Next, with reference to 1E, after the base layer 110, the black matrix layer 150, the bank layer 120, the first encapsulating layer 140, the adhesive layer 170, and the driver substrate 180 are cut along the cutting line 114, the second encapsulating layer 142 may be additionally formed on the edge 111 which is exposed after the base layer 110 is cut, on the edge 153 which is exposed after the black matrix layer 150 is cut, on the edge 1223 which is exposed after the second bank portion 122 is cut, and on the edge 143 which is exposed after the first encapsulating layer 140 is cut as needed. In this way, the second encapsulating layer 142 may cover the edge 111 of the base layer 110, the edge 153 of the black matrix layer 150, the edge 1223 of the second bank portion 122, and the edge 143 of the first encapsulating layer 140. Accordingly, the second encapsulating layer 142 featuring the water-resist effect may also contact and cover the edge 153 which is exposed after the black matrix layer 150 is cut, so that infiltration caused by water vapor passing through the black matrix layer 150 is reduced, and the reliability of the optical substrate 100 provided by this embodiment is further improved.

However, since a thickness (e.g., approximately 1 micrometer) of the black matrix layer 150 is much smaller than a thickness (e.g., approximately 8 micrometers) of the second bank portion 122, compared with the second bank portion 122, the probability of infiltration of water vapor through the black matrix layer 150 is lower. Therefore, in some embodiments, the second encapsulating layer is not required to be additionally provided to cover the edge (not shown) which is exposed after the black matrix layer is cut. Herein, the thickness of the black matrix layer 150 is, for example, a maximum thickness of the black matrix layer 150 measured in the normal direction of the base layer 110, and the thickness of the second bank portion 122 is, for example, a maximum thickness of the second bank portion 122 measured in the normal direction of the base layer 110.

In this embodiment, the first encapsulating layer 140 may contact the second encapsulating layer 142. The second bank portion 122 of the bank layer 120 may be closer to the edge 111 of the base layer 110 than the first bank portion 121. Manufacturing of the optical substrate 100 of this embodiment is completed so far.

Other embodiments are described for illustration in the following. It should be noted that the reference numerals and part of the content in the previous embodiment are used in the following embodiments, in which identical reference numerals indicate identical or similar components, and repeated description of the same technical content is omitted. Please refer to the descriptions of the previous embodiment for the omitted part, which will not be repeated hereinafter.

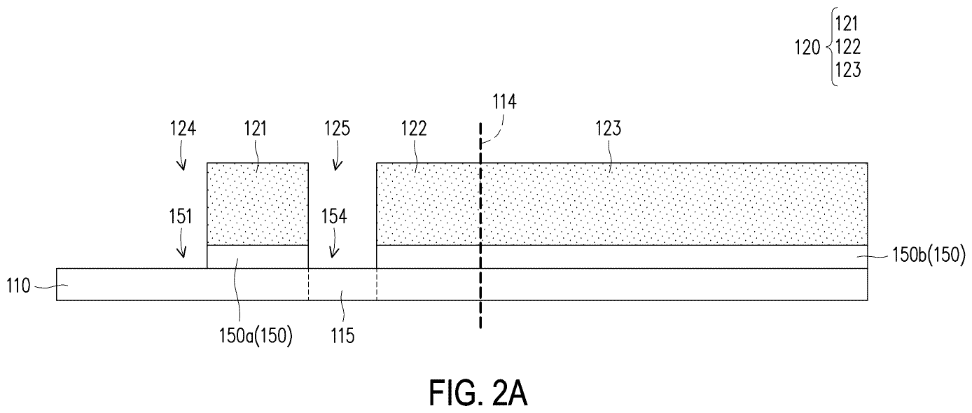

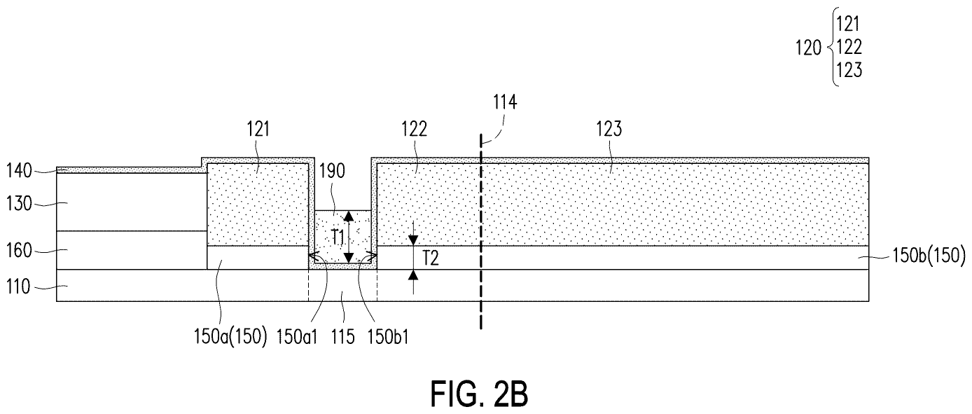

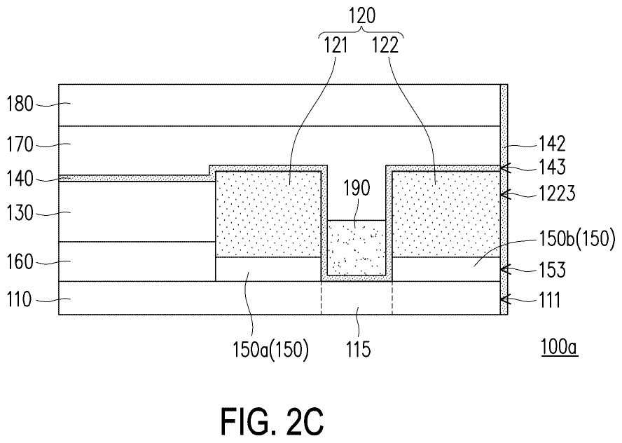

FIG. 2A to FIG. 2C are local cross-sectional schematic views of a manufacturing method of an optical substrate according to a second embodiment of the disclosure. The second embodiment shown in FIG. 2A to FIG. 2C is similar to the first embodiment shown in FIG. 1A to FIG. 1E, and therefore, the same components are denoted by the same reference numerals, and details thereof are not repeated herein. The difference between the second embodiment shown in FIG. 2A to FIG. 2C and the first embodiment shown in FIG. 1A to FIG. 1E is that the first encapsulating layer 140 may further contact and cover a side surface 150a1 of a first black matrix layer 150a in an optical substrate 100a provided by this embodiment.

To be specific, with reference to FIG. 2A, a manufacturing method similar to the abovementioned manufacturing method of FIG. 1A is adopted for manufacturing. However, the difference between the manufacturing method provided by this embodiment and the manufacturing method provided by FIG. 1A is that in the manufacturing method provided by this embodiment, the following step is further included. After the black matrix layer 150 is formed on the base layer 110, the black matrix layer 150 is patterned to form a third opening 154, the first black matrix layer 150a, and a second black matrix layer 150b. Herein, the second opening 125 may be connected to and overlap with the third opening 154, so that the second opening 125 and the third opening 154 may expose the portion 115 of the base layer 110. In other words, the portion 115 of the base layer 110 is not covered by the bank layer 120 and the black matrix layer 150. The first black matrix layer 150a may be separated from the second black matrix layer 150b through the third opening 154. The second black matrix layer 150b may be closer to the cutting line 114 of the base layer 110 than the first black matrix layer 150a. In this embodiment, patterning of the black matrix layer 150 may be executed through a yellow photolithography process or a printing process, but it is not limited thereto.

Next, with reference to FIG. 2B, a manufacturing method similar to the abovementioned manufacturing method of FIG. 1B to FIG. 1C is adopted for manufacturing. However, the difference between the manufacturing method provided by this embodiment and the manufacturing method provided by FIG. 1B to FIG. 1C is that the first encapsulating layer 140 provided by this embodiment may further contact and cover the side surface 150a1 of the first black matrix layer 150a, the first encapsulating layer 140 may further contact and cover a side surface 150b1 of the second black matrix layer 150b, and the first encapsulating layer 140 may further contact and cover the portion 115 of the base layer 110 through the second opening 125 and the third opening 154. Herein, the side surface 150a1 of the first black matrix layer 150a is the surface of the first black matrix layer 150a adjacent to the third opening 154, and the side surface 150b1 of the second black matrix layer 150b is the surface of the second black matrix layer 150b adjacent to the third opening 154.

In this embodiment, since the first encapsulating layer 140 featuring the water-resist effect may further contact and cover the side surface 150a1 of the first black matrix layer 150a, infiltration caused by water vapor passing through the first black matrix layer 150a is reduced, and the reliability of the optical substrate 100a provided by this embodiment is further improved.

In addition, the manufacturing method provided by this embodiment further includes the following step. After the first encapsulating layer 140 is formed on the bank layer 120, the wavelength conversion unit 130, and the portion 115 of the base layer 110, a light absorbing unit 190 is formed in the third opening 154 of the black matrix layer 150. The light absorbing unit 190 may be formed in the third opening 154 through, for example, a yellow photolithography process or an ink-jet printing (IJP) process. Herein, the light absorbing unit 190 may be disposed on the portion 115 of the base layer 110, and the light absorbing unit 190 may be disposed between the first bank portion 121 and the second bank portion 122 of the bank layer 120. Further, the first bank portion 121 may be disposed between the light absorbing unit 190 and the wavelength conversion unit 130. In this embodiment, a thickness T1 of the light absorbing unit 190 may be, for example, greater than or equal to a thickness T2 of the black matrix layer 150 (i.e., T1≥T2), but it is not limited thereto. Herein, the thickness T1 is, for example, a maximum thickness of the light absorbing unit 190 measured in the normal direction of the base layer 110, and the thickness T2 is, for example, a maximum thickness of the black matrix layer 150 measured in the normal direction of the base layer 110. A material of the light absorbing unit 190 may include but not limited to a light-absorbing material such as black resin, black ink, a black adhesive, other suitable light-absorbing materials, or a combination of the foregoing materials.

Next, with reference to FIG. 2C, similar to the manufacturing method shown in FIG. 1D to FIG. 1E, the adhesive layer 170 is formed on the first encapsulating layer 140, and the driver substrate 180 is disposed on the adhesive layer 170. The base layer 110, the black matrix layer 150, the bank layer 120, the first encapsulating layer 140, the adhesive layer 170, and the driver substrate 180 are cut along the cutting line 114, and the second encapsulating layer 142 is additionally formed as needed, so that the second encapsulating layer 142 may contact and cover the edge 111 which is exposed after the base layer 110 is cut, the edge 153 which is exposed after the second black matrix layer 150b is cut, the edge 1223 which is exposed after the second bank portion 122 is cut, and the edge 143 which is exposed after the first encapsulating layer 140 is cut. However, in some embodiments, the second encapsulating layer 142 is not required to be additionally disposed. Manufacturing of the optical substrate 100a of this embodiment is completed so far. Besides, in other embodiments, before the adhesive layer 170 is formed on the first encapsulating layer 140 and the driver substrate 180 is disposed on the adhesive layer 170, the base layer 110, the black matrix layer 150, the bank layer 120, the first encapsulating layer 140 may be cut along the cutting line 114.

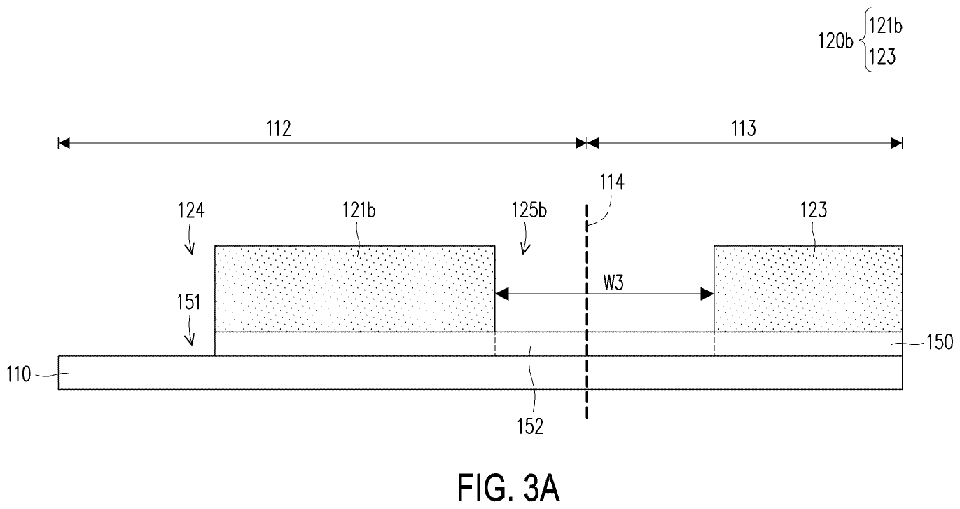

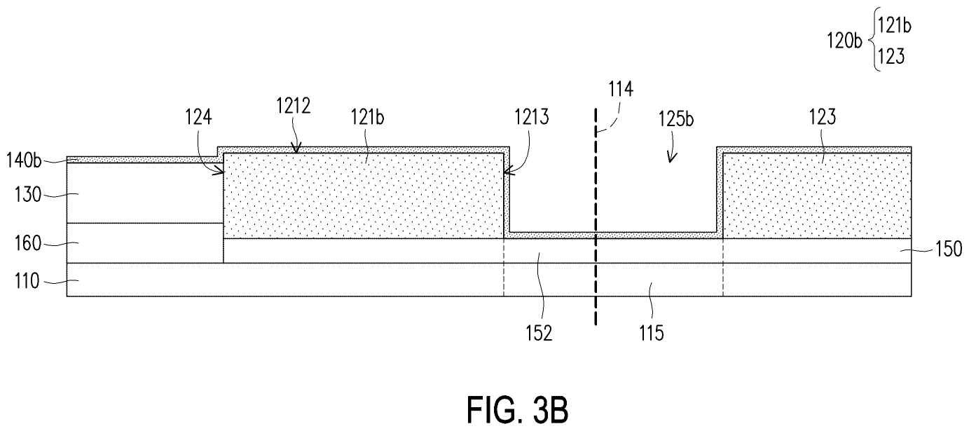

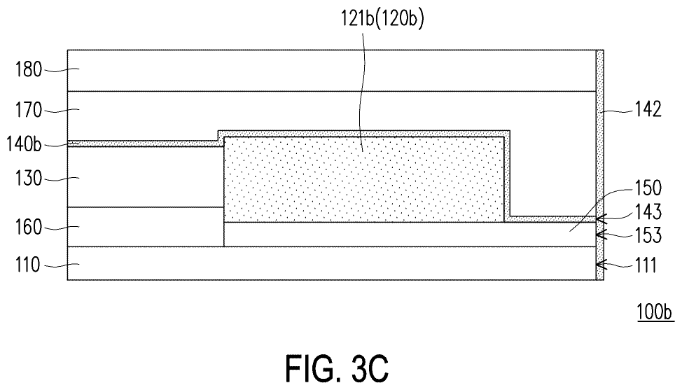

FIG. 3A to FIG. 3C are local cross-sectional schematic views of a manufacturing method of an optical substrate according to a third embodiment of the disclosure. The third embodiment shown in FIG. 3A to FIG. 3C is similar to the first embodiment shown in FIG. 1A to FIG. 1E, and therefore, the same components are denoted by the same reference numerals, and details thereof are not repeated herein. The difference between the third embodiment shown in FIG. 3A to FIG. 3C and the first embodiment shown in FIG. 1A to FIG. 1E is that a bank layer 120b does not include a second bank portion and a position of a second opening 125b of the bank layer 120b is different in an manufacturing method of an optical substrate 100b provided by this embodiment.

To be specific, with reference to FIG. 3A, a manufacturing method similar to the abovementioned manufacturing method of FIG. 1A is adopted for manufacturing. However, the difference between the manufacturing method provided by this embodiment and the manufacturing method provided by FIG. 1A is that the second opening 125b of the bank layer 120b is disposed at the junction between the active region 112 and the frame region 113 when the bank layer 120b is formed on the black matrix layer 150. That is, the second opening 125b is disposed between a first bank portion 121b and the third bank portion 123, and the third bank portion 123 may be separated from the first bank portion 121b through the second opening 125b. In this embodiment, a width W3 of the second opening 125b may be greater than or equal to 3 nm (i.e., W3≥3 nm), for example, but it is not limited thereto. Herein, the width W3 is, for example, a maximum width of the second opening 125b measured in the extending direction of the local cross-sectional view. In addition, in this embodiment, in the normal direction of the base layer 110, the cutting line 114 may overlap with the second opening 125b.

Next, with reference to FIG. 3B, similar to the manufacturing method shown in FIG. 1B to FIG. 1C, the color filtering layer 160 is formed in the opening 151, the wavelength conversion unit 130 is formed in the first opening 124, and a first encapsulating layer 140b is formed on the bank layer 120b, the wavelength conversion unit 130, and the portion 152 of the black matrix layer 150. Accordingly, the first encapsulating layer 140b featuring the water-resist effect may contact and cover the top surface 1212 and the side surface 1213 of the first bank portion 121b of the bank layer 120 together, so that infiltration caused by water vapor passing through the first bank portion 121b is reduced, and the reliability of the optical substrate 100b provided by this embodiment may be improved.

Next, with reference to FIG. 3C, similar to the manufacturing method shown in FIG. 1D to FIG. 1E, the adhesive layer 170 is formed on the first encapsulating layer 140b, and the driver substrate 180 is disposed on the adhesive layer 170. After the base layer 110, the black matrix layer 150, the first encapsulating layer 140b, the adhesive layer 170, and the driver substrate 180 are cut along the cutting line 114, the second encapsulating layer 142 may also be additionally formed on the edge 111 which is exposed after the base layer 110 is cut, on the edge 153 which is exposed after the black matrix layer 150 is cut, and on the edge 143 which is exposed after the first encapsulating layer 140b is cut as needed. Herein, the second encapsulating layer 142 may also contact and cover the edge 153 of the black matrix layer 150, so that infiltration caused by water vapor passing through the black matrix layer 150 is also reduced, and the reliability of the optical substrate 100b provided by this embodiment is further improved. Manufacturing of the optical substrate 100b of this embodiment is completed so far. Besides, in other embodiments, before the adhesive layer 170 is formed on the first encapsulating layer 140 and the driver substrate 180 is disposed on the adhesive layer 170, the base layer 110, the black matrix layer 150, and the first encapsulating layer 140b may be cut along the cutting line 114.

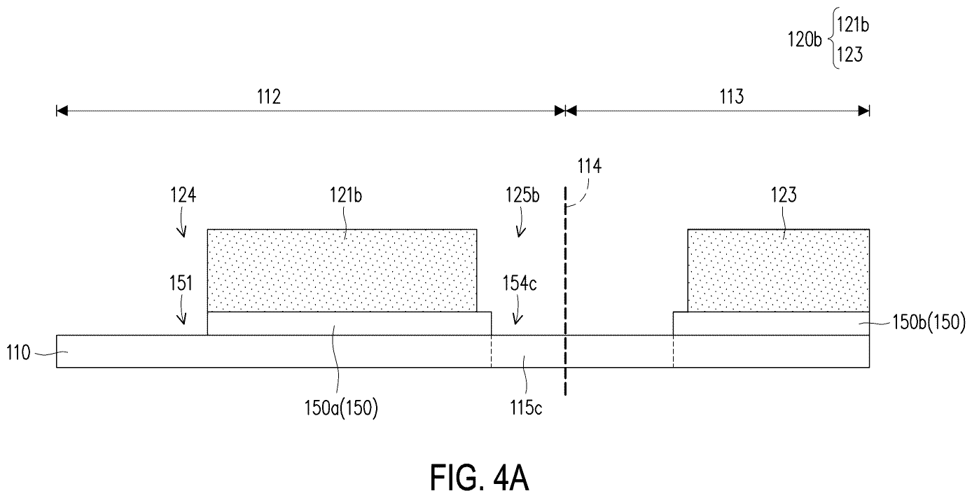

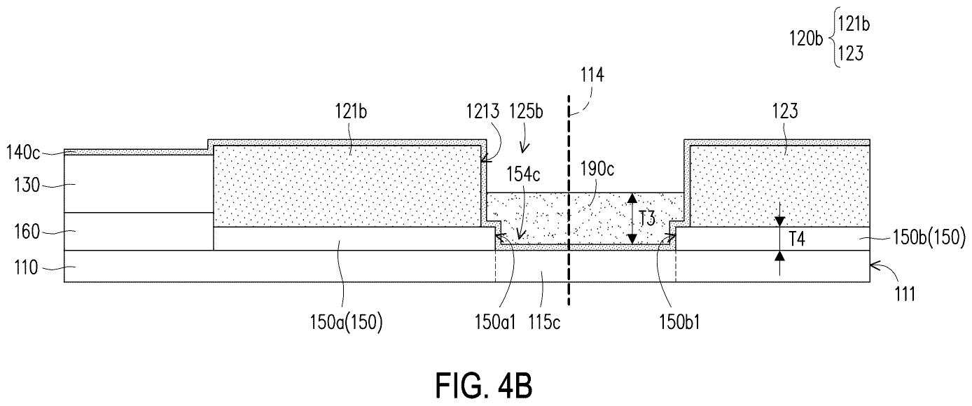

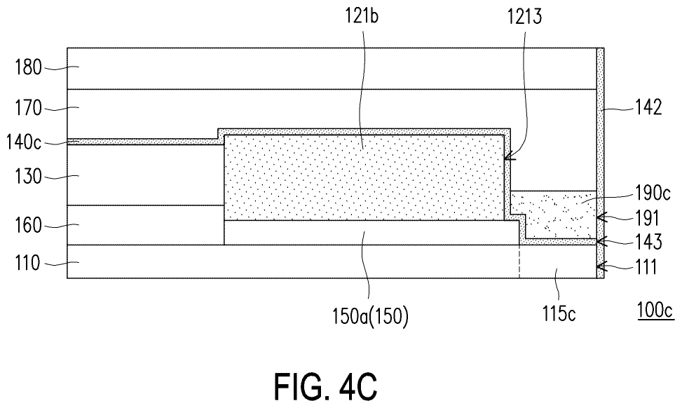

FIG. 4A to FIG. 4C are local cross-sectional schematic views of a manufacturing method of an optical substrate according to a fourth embodiment of the disclosure. The fourth embodiment shown in FIG. 4A to FIG. 4C is similar to the third embodiment shown in FIG. 3A to FIG. 3C, and therefore, the same components are denoted by the same reference numerals, and details thereof are not repeated herein. The difference between the fourth embodiment shown in FIG. 4A to FIG. 4C and the third embodiment shown in FIG. 3A to FIG. 3C is that a first encapsulating layer 140c may further contact and cover the side surface 150a1 of the first black matrix layer 150a in an optical substrate 100c provided by this embodiment.

To be specific, with reference to FIG. 4A, a manufacturing method similar to the abovementioned manufacturing method of FIG. 3A is adopted for manufacturing. However, the difference between the manufacturing method provided by this embodiment and the manufacturing method provided by FIG. 3A is that in the manufacturing method provided by this embodiment, the following step is further included. After the black matrix layer 150 is formed on the base layer 110, the black matrix layer 150 is patterned to form a third opening 154c, the first black matrix layer 150a, and a second black matrix layer 150b. Herein, the second opening 125b may be connected to and overlap with the third opening 154c, so that the second opening 125 and the third opening 154c may expose a portion 115c of the base layer 110, and the portion 115c of the base layer 110 is not covered by the black matrix layer 150. The first black matrix layer 150a may be separated from the second black matrix layer 150b through the third opening 154c. The first black matrix layer 150a is disposed in the active region 112, and the second black matrix layer 150b is disposed in the frame region 113.

Next, with reference to FIG. 4B, a manufacturing method similar to the abovementioned manufacturing method of FIG. 3B is adopted for manufacturing. However, the difference between the manufacturing method provided by this embodiment and the manufacturing method provided by FIG. 3B is that the first encapsulating layer 140 provided by this embodiment may further contact and cover the side surface 150a1 of the first black matrix layer 150a, the first encapsulating layer 140 may further contact and cover the side surface 150b1 of the second black matrix layer 150b, and the first encapsulating layer 140c may further contact and cover the portion 115c of the base layer 110 through the second opening 125b and the third opening 154c. Herein, the side surface 150a1 of the first black matrix layer 150a is the surface of the first black matrix layer 150a adjacent to the third opening 154c, and the side surface 150b1 of the second black matrix layer 150b is the surface of the second black matrix layer 150b adjacent to the third opening 154c.

In this embodiment, since the first encapsulating layer 140 featuring the water-resist effect may further contact and cover the side surface 150a1 of the first black matrix layer 150a, infiltration caused by water vapor passing through the first black matrix layer 150a is reduced, and the reliability of the optical substrate 100c provided by this embodiment is further improved.

In addition, the manufacturing method provided by this embodiment further includes the following step. After the first encapsulating layer 140c is formed on the bank layer 120b, the wavelength conversion unit 130, and the portion 115c of the base layer 110, a light absorbing unit 190c is formed in the third opening 154c of the black matrix layer 150. Herein, the light absorbing unit 190c may be disposed on the portion 115c of the base layer 110, and the light absorbing unit 190c may be disposed between the first bank portion 121b and the third bank portion 123 of the bank layer 120. The light absorbing unit 190c may be disposed at a side of the first bank portion 121b adjacent to the edge 111. Further, the first bank portion 121b may be disposed between the light absorbing unit 190c and the wavelength conversion unit 130. In this embodiment, a thickness T3 of the light absorbing unit 190c may be, for example, greater than or equal to a thickness T4 of the black matrix layer 150 (i.e., T3≥T4), but it is not limited thereto. Herein, the thickness T3 is, for example, a maximum thickness of the light absorbing unit 190c measured in the normal direction of the base layer 110, and the thickness T4 is, for example, a maximum thickness of the black matrix layer 150 measured in the normal direction of the base layer 110.

Next, with reference to FIG. 4C, similar to the manufacturing method shown in FIG. 3C, the adhesive layer 170 is formed on the first encapsulating layer 140c, and the driver substrate 180 is disposed on the adhesive layer 170. The base layer 110, the first encapsulating layer 140c, the light absorbing unit 190c, the adhesive layer 170, and the driver substrate 180 are cut along the cutting line 114, and the second encapsulating layer 142 is additionally formed as needed, so that the second encapsulating layer 142 may contact and cover the edge 111 which is exposed after the base layer 110 is cut, the edge 143 which is exposed after the first encapsulating layer 140c is cut, and the edge 191 which is exposed after the light absorbing unit 190c is cut. However, in some embodiments, the second encapsulating layer 142 is not required to be additionally disposed. In this embodiment, the second encapsulating layer 142 may contact the first encapsulating layer 140. Manufacturing of the optical substrate 100c of this embodiment is completed so far. Besides, in other embodiments, before the adhesive layer 170 is formed on the first encapsulating layer 140 and the driver substrate 180 is disposed on the adhesive layer 170, the base layer 110, the first encapsulating layer 140c, and the light absorbing unit 190c may be cut along the cutting line 114.

In view of the foregoing, in the optical substrate and the manufacturing method thereof provided by the embodiments of the disclosure, through once processing, the first encapsulating layer may contact and cover the top surface and the side surface of the first bank portion of the bank layer together, and in this way, infiltration caused water vapor passing through the first bank portion may be accordingly reduced. In turn, reliability of the optical substrate provided by the embodiments of the disclosure may be improved, especially for the optical substrate including the wavelength conversion unit that is susceptible to failure as affected by external water vapor or for a spliced display (zero border tiling display) including the optical substrate, but it is not limited thereto. In addition, in the embodiments of the disclosure, the second encapsulating layer may be additionally disposed as needed, and the second encapsulating layer may be arranged to contact and cover the edge of the black matrix layer. In this way, infiltration caused by water vapor passing through the black matrix layer may be reduced, and the reliability of the optical substrate may thus be improved. Further, in some embodiments of the disclosure, since the first encapsulating layer may further contact and cover the side surface of the first black matrix layer, infiltration caused by water vapor passing through the first black matrix layer is reduced, and the reliability of the optical substrate is therefore further improved.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An optical substrate, comprising:
a base layer;
a light-absorbing structure, disposed on the base layer;
a bank layer, disposed on the light-absorbing structure, comprising a first bank portion separated from a second bank portion; and
an adhesive layer, disposed on the bank layer,
wherein in a cross-sectional view, a portion of the light-absorbing structure is overlapped with an opening defined by the first bank portion and the second bank portion of the bank layer, and a portion of the adhesive layer is disposed in the opening.

2. The optical substrate according to claim 1, further comprising:
a second opening adjacent to the first opening, wherein the first bank portion is between the first opening and the second opening, wherein the light-absorbing structure does not overlap with the second opening.

3. The optical substrate according to claim 2, further comprising:
a wavelength conversion unit, disposed in the second opening, wherein the wavelength conversion unit does not overlap with the first opening.

4. The optical substrate according to claim 3, wherein in a cross-sectional view, a top surface of the wavelength conversion unit is not higher than a top surface of the first bank portion.

5. The optical substrate according to claim 4, further comprising:
an encapsulating layer disposed on the wavelength conversion unit, the first bank portion and the light-absorbing structure, wherein in a cross-sectional view, a first portion of a top surface of the encapsulating layer overlapped with the wavelength conversion unit is higher than a second portion of the top surface of the encapsulating layer overlapped with the light-absorbing structure.

6. The optical substrate according to claim 5, wherein the second portion of the top surface of the encapsulating layer is lower than a third portion of the top surface of the encapsulating layer overlapped with the first bank portion.

7. The optical substrate according to claim 1, wherein in a cross-sectional view, the light-absorbing structure extend from below the first bank portion to below the second bank portion.

8. The optical substrate according to claim 7, further comprising:
an encapsulating layer disposed between the adhesive layer and the light-absorbing structure, wherein in a cross-sectional view, a portion of the encapsulating layer extended in the first opening.

9. The optical substrate according to claim 8, the first bank portion comprise a first surface face to the light-absorbing structure, a second surface opposite to the first surface and a third surface connect the first surface and the second surface, wherein in a cross-sectional view, the encapsulating layer completely covers the third surface, and disposed between the third surface and the adhesive layer.

10. The optical substrate according to claim 9, the second bank portion comprise a fourth surface face to the light-absorbing structure, a fifth surface opposite to the fourth surface and a sixth surface connect the fourth surface and the fifth surface, wherein in a cross-sectional view, the encapsulating layer completely covers the sixth surface, and disposed between the sixth surface and the adhesive layer.

11. A manufacturing method of an optical substrate, comprising:
providing a base layer;
forming a bank layer on the base layer, wherein the bank layer has a first opening and a second opening;
forming a wavelength conversion unit in the first opening; and
forming a first encapsulating layer on the bank layer, the wavelength conversion unit, and a portion of the base layer corresponding to the second opening.

12. The manufacturing method according to claim 11, wherein the wavelength conversion unit is formed in the first opening through an ink-jet printing process.

13. The manufacturing method according to claim 11, wherein before the step of forming the bank layer on the base layer, the manufacturing method further comprises:
forming a black matrix layer on the base layer.

14. The manufacturing method according to claim 13, wherein the first encapsulating layer contacts the black matrix layer through the second opening.

15. The manufacturing method according to claim 13, further comprising:
patterning the black matrix layer to form a third opening, wherein the second opening overlaps the third opening, and the first encapsulating layer contacts the base layer through the second opening and the third opening.

16. The manufacturing method according to claim 15, further comprising:
forming a light absorbing unit in the third opening.

17. The manufacturing method according to claim 11, further comprising:
cutting the base layer and the first encapsulating layer along a cutting line, wherein the cutting line overlaps the second opening.

18. The manufacturing method according to claim 17, wherein after the step of cutting the base layer and the first encapsulating layer along the cutting line, the manufacturing method further comprises:
forming a second encapsulating layer on an exposed edge of the base layer after being cut, wherein the first encapsulating layer contacts the second encapsulating layer.

19. The manufacturing method according to claim 11, further comprising:
cutting the base layer, the bank layer, and the first encapsulating layer along a cutting line, wherein the cutting line is adjacent to a side of the second opening away from the first opening.

20. The manufacturing method according to claim 19, wherein after the step of cutting the base layer, the bank layer, and the first encapsulating layer along the cutting line, the manufacturing method further comprises:
forming a second encapsulating layer on an exposed edge of the base layer after being cut, wherein the first encapsulating layer contacts the second encapsulating layer.
